(19) United States
(12) Patent Application Publication
(10) Pub. No.: US 2007/0128895 A1
(43) Pub. Date: Jun. 7, 2007

(54) Redundant automation system for controlling a techinical device, and method for operating such an automation system

(76) Inventors: Dieter Kleyer, Herzogenaurach (DE); Wolfgang Ott, Baiersdorf (DE)

Correspondence Address: SIEMENS CORPORATION;INTELLECTUAL PROPERTY DEPARTMENT, 170 WOOD AVENUE SOUTH, ISELIN, NJ, 08830, US

(21) Appl. No.: 10/579,485

(22) PCT Filed: Nov. 17, 2003
(86) PCT No.: PCT/DE03/03793

§ 371 Date: May 16, 2006

(51) Int. Cl. H05K 1/00

(52) U.S. Cl. 439/76.1

(57) ABSTRACT

The invention relates to a redundant automation system, and a method for operating one such automation system. The inventive automation system comprises two automation appliances with which a common memory unit is associated, on which status data of the automation appliances can be stored. In this way, the automation appliances have direct access to a common database and a memory compensation is dispensed with in the event of an error during the switchover to the standby automation appliance.

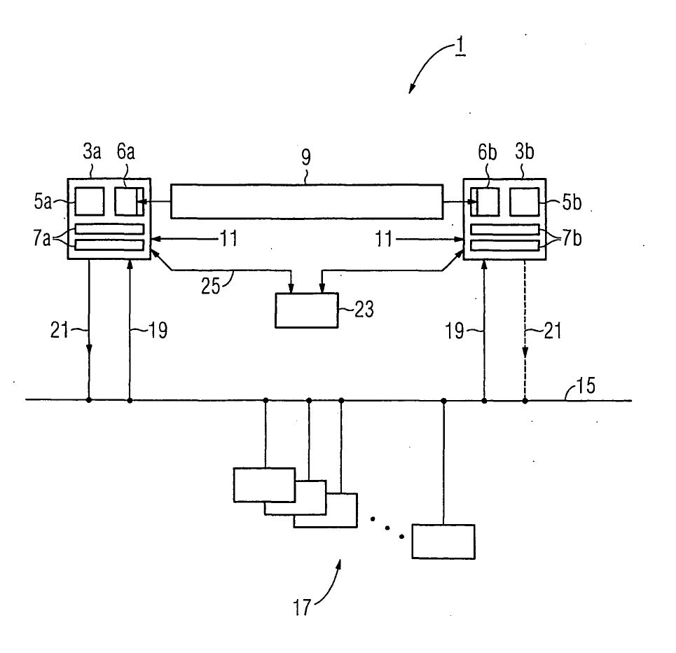

### CROSS REFERENCE TO RELATED APPLICATIONS

This application is the US National Stage of International Application No. PCT/DE2003/003793, filed Nov. 17, 2003 and claims the benefit thereof and is incorporated by reference herein in their entirety.

### FIELD OF THE INVENTION

The invention relates to a redundant automation system for controlling a technical device and to a method for operating such an automation system, wherein at least two automation devices are present. In this arrangement a first of said automation devices is operated as the master automation device and a second of the automation devices is operated as a standby automation device.

### BACKGROUND OF THE INVENTION

With regard to the automation of a technical installation—in particular a power station—the permanent availability of devices and systems is one of the most important requirements.

For reasons of safety, in order to exclude a potential risk, and also for reasons of assuring a reliable supply of electrical energy or goods, the failure of automation systems and an associated shutdown of important technical installations must be avoided as far as possible.

In order to solve this problem there are known in the prior art so-called highly available automation systems, for example the SIMATIC S-7 H from Siemens, in which practically all the components including the memory and power supply units are present redundantly, so that in the event of an error in an automation device an interrupt-free switchover can be performed to another, identically configured automation device. In this arrangement the automation devices are synchronized with one another in terms of their command execution, with the result that the same data is processed completely parallel in time in both automation devices and the same commands are executed. In this way it is possible for a standby automation device operated in such a way to take over the function of a master automation device that is affected by an error.

Highly available automation systems of this kind have until now been available virtually exclusively on the basis of what are referred to as programmable logic controllers (PLCs), have been complicated to use and very expensive to purchase.

### SUMMARY OF THE INVENTION

The object of the invention is therefore to specify an automation system of the kind cited at the beginning which is simpler in design and in which in particular standard components from personal computer technology can be used as far as possible.

The object is achieved with regard to the automation system by means of a redundant automation system for controlling a technical device having the features recited in the claims.

The invention is based here on the consideration that one of the most important requirements for implementing a redundant automation system consists in the provision of an up-to-date database which describes the status of the technical device and of the automation system. A switchover from the master automation device to the standby automation device without noticeable delay can only be achieved in this case if the same current data is available to both automation devices at the time an error occurs, so that a switchover to the standby device is possible instantaneously and without “data jumps”.

In prior art highly available programmable logic controllers this is achieved by both automation devices being of identical design and in each case including, among other components, a memory unit into which the same data is written on account of the command-synchronous processing already described above and from which the same data is read out.

In contrast thereto, in the present invention it is provided that although two automation devices are in fact present, only one common (shared) memory unit is provided for these and both automation devices have read and write access to said one common memory unit. To that extent the implementation overhead is substantially reduced compared to the prior art, since on the one hand only one memory unit is required and on the other hand as a consequence of this the synchronization overhead required between a plurality of memory units of the automation devices is unnecessary.

By far the majority of failures of automation devices are due to malfunctions of, for example, the input or output cards, the power supply or the CPUs of the automation devices; seen from that perspective the present invention therefore offers a cost-effective, simplified solution for most of the redundancy problems to be overcome in automation in practice.

Although a number of PC-based automation solutions already exist, until now these have not yet been able to guarantee a jolt-free switchover to the standby automation device, since the required synchronization of the databases which the automation devices access cannot take place at the necessary speed using known means. A jolt-free switchover in this context means that the switchover from the master to the standby automation device happens practically without any effects on the input and output signals of the automation system, so that in particular control actions are continued at precisely the point at which the defective automation device aborted the control action. Consequently, so-called initial values relating to the past history of the control action (included here are in particular closed-loop control algorithms which have an integral and/or differential component) must be available to the standby automation system at the time it takes over control.

The present invention solves the problem of an up-to-date database for the automation devices to the extent that only one common memory unit is provided therefor.

A solution for implementing such a memory unit in PC technology in the case of an automation system according to the invention includes for example the use of what are referred to as “reflective memories”, which are obtainable as commercially available PC modules.

By this means PCs, workstations or “embedded systems” (in particular running under different operating systems) are given the capability to access a common database practically in real time.

In the case of a local computer the reflective memory module is located for example in the address space of the common memory of the computers participating in a network. Data can then be written from any automation level, in particular also by a piece of application software, directly into this memory area and can also be read out from this memory area. Data that the local computer writes into this “reflective memory” is then automatically available to all the other computers in parallel and without time delay.

Because of the special technical embodiment of the reflective memory module the data transfer taking place in this process between the computers does not affect the normal performance of this computer.

In an advantageous embodiment of the invention a monitoring module is also provided, by means of which the operation of the master automation system can be monitored and in the event of an error affecting the master automation device a switchover to the standby automation device is made possible, said standby automation device thereupon taking over the function of the former master automation device.

Monitoring of the device operation including error detection is implemented in this embodiment. In this case, for example, the monitoring module includes the evaluation of what is referred to as a “vital sign” of the master automation device, wherein e.g. during each cycle of the checking a characteristic value is changed if the master automation device is fully functional. Should this characteristic value not be changed during a cycle, this is an indication of a malfunction of this automation device and the monitoring module performs the switching operation to the assigned standby automation device.

Possible problems which prevent the aforesaid characteristic value from being changed include, for example, hardware faults and/or operating system errors and/or application software errors.

In a further advantageous embodiment of the invention there is present in the common memory area status data which describes the current operating status of the technical device and of the automation system immediately prior to the time an error occurs in the master automation device.

This enables the standby automation device to take over the function of the former master automation device immediately, since all the data necessary for this is stored in the common memory area and can be read out by the standby automation device for further processing without time delay.

In this case the status data should include in particular such data which corresponds to initial values of closed-loop control algorithms, so that by means of these initial values the history of the relevant control operations will also be known to the standby automation device and the relevant control adjustments can continue to be performed without interruption by the standby automation device.

The status data additionally includes such input and output data of the technical device which is captured by the automation system and/or output to the technical device. The totality of this data is referred to as the process image.

The switchover is performed particularly advantageously in a jolt-free manner, in that at least a part of the data residing in the common memory area is immediately processed further by the standby automation device as the current status image of the technical device and the automation system.

In this case the switchover between the master automation device and the standby automation device takes place practically without delay, with the standby automation device taking over control of the technical device with no interruption to operation.

The invention also leads to a method for operating a redundant automation system for controlling a technical device with the features of the claims.

Advantageous embodiments of the method according to the invention are set forth in the associated dependent claims.

### BRIEF DESCRIPTION OF THE DRAWINGS

An exemplary embodiment of the invention is described in more detail below with reference to the drawing, in which:

FIGURE shows a redundant automation system according to the invention.

### DETAILED DESCRIPTION OF THE INVENTION

The figure depicts an inventive redundant automation system 1 which comprises automation devices 3a, 3b. In this case a first automation device is embodied as a master automation device 3a which is responsible for controlling a technical device. The signals from the technical device and the control commands to the technical device are processed here by field devices 17 and transferred to the automation devices 3a, 3b via a field bus 15.

In the event of an error in the first automation device 3a, a second automation device is available which is embodied as a standby automation device 3b and can take over the control functions of the first automation device 3a.

A monitoring module 23 is provided for the purpose of error detection and switchover from the first automation device 3a to the second automation device 3b. Among other things this evaluates a vital sign 25 of the first automation device 3a and in the event of an error switches over to the second automation device 3b which thereupon takes over the control functions of the former master automation device 3a.

The automation devices 3a, 3b each possess a CPU 5a, 5b and possibly a memory 6a, 6b. They are preferably embodied as personal computers in which the control functions are invoked and executed as tasks 7a, 7b. In comparison with conventional programmable logic controllers these automation tasks 7a, 7b execute considerably faster, for which reason with PC-based automation devices implemented in this way a task synchronization takes place rather than a command synchronization. The corresponding tasks 7a, 7b in each case are synchronized by means of interrupts 11.

In normal operation, when the first automation device is operating without error as a master automation device 3a, the data from the technical device is captured by the field devices 17 and continuously read in by both automation devices 3a, 3b by means of at least one read operation 19 in each case; however, the output of control commands and other actions to components of the technical device takes place only through the master automation device 3a by means of at least one write operation 21.

After a switchover to the former standby automation device in the event of an error this write operation 21 is taken over by the second automation device 3b; this is indicated in the figure by a dashed connection from the second automation device 3b to the field bus 15.

During the synchronization of the automation tasks 7a, 7b by means of the interrupts 11, timers, counters, process data and, where applicable, further internal and external data are synchronized before each task call.

According to the invention the two automation devices 3a, 3b are assigned one memory unit 9 to which both automation devices 3a, 3b have access. Essentially, status data of the automation devices 3a, 3b is stored in said memory unit, the memory unit 9 comprising at least one memory area which can be written to and read by both automation devices 3a, 3b. In this way at least the data present in this memory area is made available in parallel to the automation devices 3a, 3b. Since the two automation devices 3a, 3b therefore have a common database in the form of the memory unit 9 to which they each have access, if an error occurs in the master automation device 3a no memory synchronization is required between the automation devices 3a and 3b, at least insofar as the synchronization of the above cited status data is concerned. For this reason a switchover from the master automation device 3a to the standby automation device 3b can be performed very quickly and seamlessly (jolt-free) in the event of an error, while at the same time the implementation overhead is reduced in comparison with known redundant automation systems. The status data of the automation devices 3a, 3b that is stored in the common memory area of the memory unit 9 includes all data which describes a current operating status of the automation devices 3a, 3b, such as, for example, the current values of the signals transmitted from the technical device to the automation devices (process image), the current values of the signals transmitted from the master automation device to the technical device and commands, as well as, if necessary, current initial values of control algorithms which comprise at least one differentiating and/or integrating control element.

Knowledge of the current initial value is important at the time an error occurs in the master automation device, so that the former standby automation device can continue to perform the relevant control actions continuously, in particular without a jump in a controlled variable.

The memory unit 9 is preferably embodied as what is referred to as a “reflective memory” module, which is available as a module for use with personal computers. Said module is physically installed preferably in one of the automation devices 3a, 3b, the data that this automation device writes into the module then being available also to all the other automation devices.

To sum up, the present invention can be described as follows:

In a redundant automation system (1) according to the invention and in a method for operating such an automation system (1), two automation devices (3a, 3b) are provided to which a common memory unit is assigned in which status data of the automation devices (3a, 3b) can be stored. The automation devices (3a, 3b) therefore have direct access to a common database and in the event of an error there is no need for a memory synchronization to be performed during the switchover to the standby automation device (3b).

1-8. (canceled)

9. A redundant automation system for controlling a technical device, comprising:
a first automation device identified as a master automation device;
a second automation device identified as a standby automation device, and
a memory unit operatively connected to the first and second automation devices that includes a common memory area that can be written to and read by the first and second automation devices and stores status data of the first and second automation devices wherein the data present in the memory area is available in parallel to the first and second automation devices.

10. The redundant automation system as claimed in claim 1, further comprising:
a monitoring module that monitors the operation of the master automation device for malfunctions, and
if a malfunction occurs, then a switchover from the master automation device to the standby automation device is performed,
wherein the standby automation device takes over the function of the former master automation device.

11. The redundant automation system as claimed in claim 2, wherein the common memory area stores status data that describes the current operating status of the technical device and of the automation system immediately prior to a time an error occurs in the master automation device.

12. The redundant automation system as claimed in claim 3, wherein the switchover takes place in a jolt-free manner such that a portion of the data residing in the common memory area is immediately processed by the standby automation device as the current status image of the technical device and the automation system.

13. A method for operating a redundant automation system for controlling a technical device, comprising:
operating a first automation device as a master;
operating a second automation device as a standby; and
storing status data of the first and second automation devices in a memory unit wherein a common memory area of the memory unit can be written to and read from by the at least two automation devices, wherein the data present in the memory area is available in parallel to the automation devices.

14. The method as claimed in claim 5, wherein the operation of the master automation device is monitored for errors and if an error occurs in the master automation device then a switchover is made to the standby automation device that takes over the function of the former master automation device.

15. The method as claimed in claim 6, wherein there is present in the common memory area status data which describes the current operating status of the technical device and the automation system immediately before the time an error occurs in the master automation device.

16. The method as claimed in claim 7, wherein the switchover is performed in a jolt-free manner such that a portion of the data residing in the common memory area is immediately processed by the standby automation device as the current status image of the technical device and the automation system.
